(19) United States
(12) Patent Application Publication
(10) Pub. No.: US 2008/0163013 A1
(43) Pub. Date: Jul. 3, 2008

(54) Memory testing system and method

(76) Inventors: Robert James Landers, Allen, TX (US); Vinay Burjinroppa Jayaram, Allen, TX (US)

Correspondence Address: TEXAS INSTRUMENTS INCORPORATED, P O BOX 655474, M/S 3999, DALLAS, TX, 75265, US

(21) Appl. No.: 11/648,142

(22) Filed: Dec. 29, 2006

(51) Int. Cl. G11C 29/04; H03K 19/21

(52) U.S. Cl. 714/719; 326/52

(57) ABSTRACT

Methods, circuits and systems are provided for testing random-access memory (RAM) devices. In one embodiment, one or more test vectors are written to a RAM device. Bit-signals are read from the RAM device one line at a time and are segregated into respective sub-pluralities. Each sub-plurality is tested to determine if there is logical value equality among all of the respective bit-signals. Test signals corresponding to each of the sub-plurality determinations are provided. The test signals are collectively evaluated and an overall equality or non-equality signal is derived.

### BACKGROUND

Random-access memory (RAM) technology has matured to the extent that present device topologies are several times the data width of early memory devices. Memories that are two hundred fifty-six and five hundred twelve bits wide are now routinely manufactured. RAM topologies that are wider still can probably be expected in the foreseeable future.

It is common practice to test such RAM devices in significant numbers, be they commercially deliverable lots, statistically viable populations of a new RAM design, etc. Such testing typically involves writing and reading known data (i.e., vectors) to and from each tested device while detecting any discrepancies that occur. The cost and complexity of such memory testing systems are of growing concern. As RAM devices have become wider (i.e., more bits per line), the number of required connection points, signal traces and wires, and discrete components in the test assembly have increased correspondingly. State-of-the-art RAM topologies are such that considerable complexity and cost is involved in constructing and operating the required test equipment.

Numerous testing methods are used to combat cost and/or complexity issues as exemplified above. One such method is known as “data slicing”. While this approach substantially simplifies the required test apparatus, it has the undesirable effect of greatly increasing the apparent depth of the RAM device under test. In turn, this apparent increase in depth increases the number of test cycles and overall time required to test a particular RAM device.

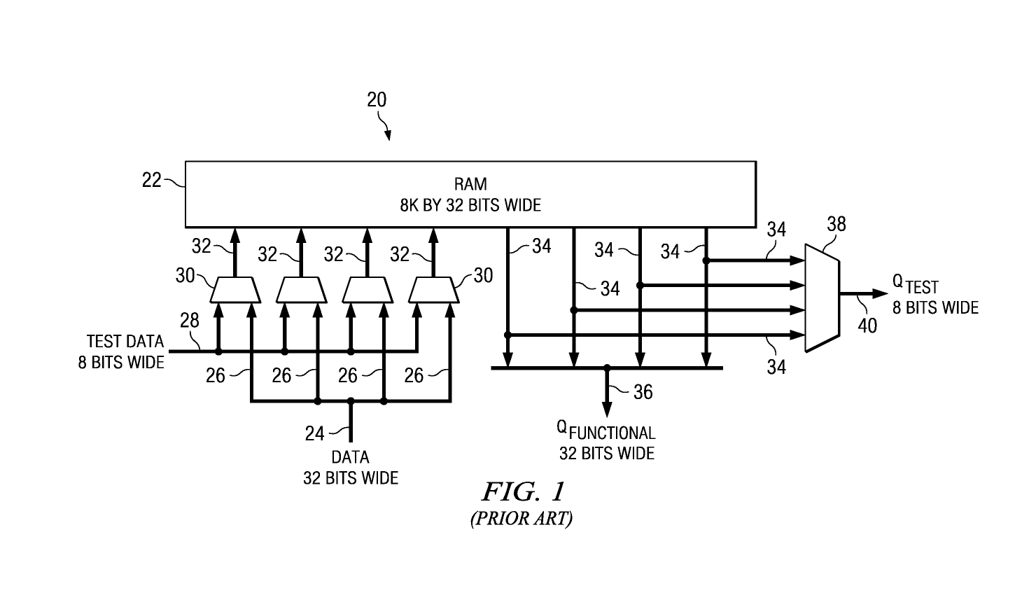

One known memory testing topology 20 is depicted in FIG. 1. The topology 20 includes a random access memory (RAM) device 22 to be tested. The exemplary RAM device 22 is defined as being thirty-two bits wide by 8 k (i.e., 8,096) lines deep. Thus, the RAM device 22 of FIG. 1 is configured to store 8 k standard double-words of digital data. It is to be understood that the exemplary topology 20 of FIG. 1 can be applied to RAM devices of other storage configurations (i.e., other data widths and/or depths).

FIG. 1 also depicts a bit-signal pathway 24 that is thirty-two bits wide representing data to be stored in the RAM device 22. The bit-signal pathway 24 is segregated into four respective sub-pluralities 26, each being eight bits, or one standard byte, in width. Also depicted is a test vector 28 that is eight bits in width. It is to be understood that the test vector 28 includes predefined data content such as, for example, all “one” bits, all “zero” bits, alternating “one” and “zero” bits, etc. In any case, the content of the test vector 28 has been predetermined and is suitable for purposes of testing the RAM device 22.

The topology 20 of FIG. 1 further includes four multiplexers 30. As depicted, each multiplexer 30 is configured to receive a respective one of the bit-signal sub-pluralities 26 and the test vector 28. Each multiplexer 30 is further configured to provide a respective eight-bit signal output 32, consisting of six bit signals taken from the respective sub-plurality 26 and two bit signals taken from the test vector 28. In this way, the four resulting signal outputs 32 total a full double-word. The four resulting signal outputs 32, which can vary from line to line, are written to the RAM device 22 until all or some predetermined portion of the RAM device 22 has been written with test data.

After the RAM device 22 has been written to (fully or partially), the test data is then progressively read from the RAM device 22, one double-word (i.e., line) at a time. This data is received from the RAM device 22 by way of four respective eight-bit signal pathways 34. These four pathways 34 collectively define thirty-two bit-signals 36. The four bit-signal pathways 34 are also routed to a multiplexer 38. The multiplexer 38 is configured to take two bit-signals from each of the pathways 34 and combine them into a test output byte 40. In this way, each test output byte 40 is derived from a double-word that was previously stored in the RAM device 22. Each test output 40 byte can then be evaluated by other circuitry or means (not shown) to determine if there are discrepancies between a portion of the test data loaded into the RAM device 22, and that portion which is read from the RAM device 22.

Because each test output byte 40 represents only one-fourth of the total width of the RAM device 22, four iterations are required to fully test the overall storage capacity of the RAM device 22. This time expenditure trade-off has been tolerated in the past in order to simplify the overall testing apparatus. However, a solution that avoids both excessive testing time and increased test apparatus complexity is desired.

### SUMMARY

In one embodiment, logic circuitry is coupled to all of the data outputs of a RAM device under test. Such data outputs are discretely referred to as bit signals. As test vectors are read from the RAM device, the logic circuitry determines if all of the bit-signals within selected sub-pluralities of the bit-signals are of the same (equal) logical value. An output signal is provided indicating if such equality has been determined for all of the sub-pluralities, on a line-by-line basis. This output signal can then be used alone or in conjunction with other testing techniques to evaluate the storage and read integrity of the RAM device under test.

### BRIEF DESCRIPTION OF THE CONTENTS

FIG. 1 illustrates an exemplary RAM testing technique in accordance with the prior art.

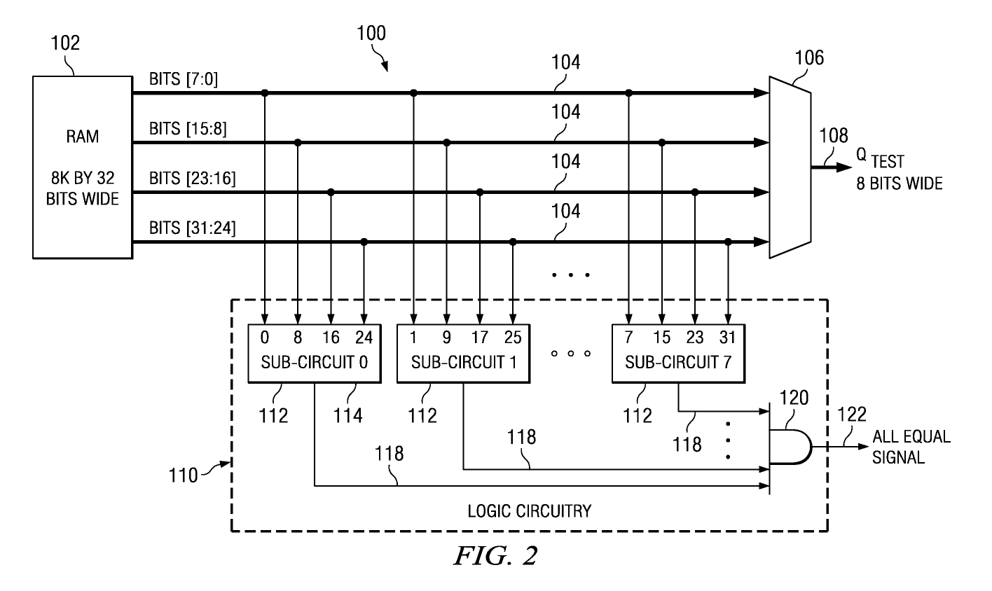

FIG. 2 illustrates RAM testing system in accordance with one embodiment.

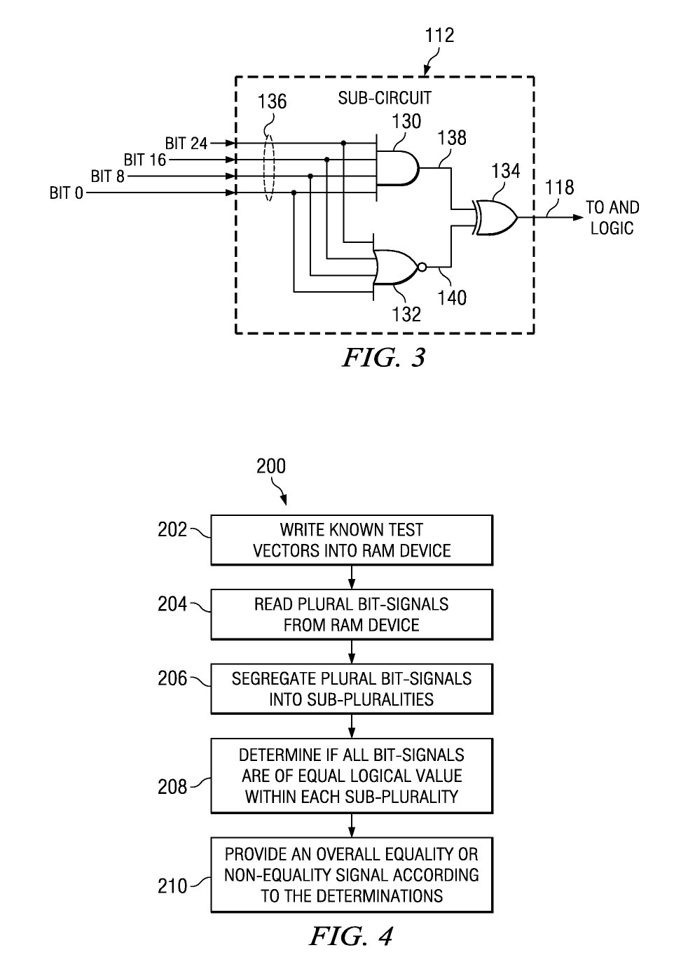

FIG. 3 illustrates sub-circuitry details of the system of FIG. 2.

FIG. 4 illustrates method steps in accordance with another embodiment.

### DETAILED DESCRIPTION

Overview of Testing System

FIG. 2 depicts portions of a RAM testing system 100 in accordance with one embodiment. The system 100 includes a RAM device 102 under test. The RAM device 102 is understood to be received in a socket or other suitable interface means (not shown) and is in signal communication with the balance of the system 100. The RAM device 102 is depicted as being 8 k lines deep by thirty-two bits (one double-word) in width. Thus, the overall storage capacity of the RAM device 102 is: (8,096×32)=259,072 bits total. While a particular configuration of RAM device 102 is depicted in FIG. 2, it is to be understood that the means and methods presented herein can be suitably adapted and applied to testing other RAM device topologies (i.e., other data widths and/or depths). Therefore, the RAM device 102, as well as the system 100 overall, are exemplary and non-limiting of the teachings herein. The RAM device 102 provides a total of thirty-two data output lines, or bit-signals, depicted in FIG. 2 as four groups of signal pathways 104. Each signal pathway 104 is eight bit-signals in width, or one byte.

The system 100 also includes a multiplexer (MUX) 106 that receives all of the signal pathways 104. The multiplexer 106 is configured to take (or select) two predetermined bit-signals from each incoming bit-signal pathway 104 and combine them into an output 108 that is eight bit-signals in width. Under typical operation of the system 100, the multiplexer 106 produces one output 108 byte for each double-word (thirty-two bits) of data that is read from the RAM device 102 under test. Each of these output 108 bytes can be sent on to other testing and evaluation circuitry (not shown) as desired.

The system 100 further includes logic circuitry 110. The logic circuitry 110, as will be described in detail below, can be provided in any suitable manner including, but not limited to: a circuit comprising one or more discrete logic devices; an application specific integrated circuit (ASIC); a programmable logic device; etc. Other suitable means can also be used to define and provide the logic circuitry 110, or selected portions thereof.

The logic circuitry 110 of FIG. 2 includes a plurality of logic sub-circuits 112. While a total of three sub-circuits 112 are depicted in FIG. 2, it is to be understood that under the exemplary system 100, a total of eight such sub-circuits 112 would be present. Each of the sub-circuits 112 is configured to receive four respective bit-signals, one from each of the signal pathways 104. For example, the sub-circuit 114 is configured to receive the four bit-signals designated [0, 8, 16, 24] as provided (read) from the RAM device 102. In this way, the eight sub-circuits 112 collectively receive all thirty-two bit-signals that are provided by the RAM device 102 during typical testing procedures.

Each sub-circuit 112 of FIG. 2 is configured to evaluate the four respectively received bit-signals and provide a signal 118 indicating if the four bit-signals are all of equal logical value. For example, the sub-circuit 114 provides a signal 118 asserted to indicating equality if all bit-signals [0, 8, 16, 24] are of logic “low” (i.e., “zero”) value, or logic “high” (i.e., “one”) value. In the event that one or more bit-signals are not the same as the others, the corresponding signal 118 is asserted to indicate non-equality. Thus, each signal 118 indicates either equality or non-equality, accordingly. In another embodiment, the corresponding sub-circuits 112 can be configured to receive other designated bit-signals read from the RAM device 102. For example, a particular sub-circuit 112 can be configured to receive bit-signals designated [0, 1, 2, 3], etc.

The logic circuitry 110 of the system 100 includes an AND logic gate 120. The AND logic gate 120 is configured to receive all of the signals 118 and provide an output signal 122 asserted to indicate equality if, and only if, all of the sub-circuits 112 indicated equality for the bit-signals respectively tested by each. In this way, the output signal 122 provides a go/no-go type indication with respect to all of the bit-signals read from the RAM device 102. Thus, the output signal 122 provides a single test point that can be used alone or in conjunction with the output byte 108 in while the RAM device 102 is under test.

During typical testing operations of the system 100 of FIG. 2, the RAM device 102 is pre-loaded—either completely or address-selectively—with double-word test vectors wherein selected four-bit groupings are asserted either all “low” or all “high” (i.e., “zero” or “one”, etc.) For example, one such test vector could be defined as: [11111111111111111111111111111111]. In such a simple case, all bits are asserted “one”. However, under the logic circuitry 110 of FIG. 2, another exemplary test vector is: [01101111011011110110111101101111]. In this case, every four bit grouping [0, 8, 16, 24] and [3, 11, 19, 27] is asserted “zero” and will be evaluated as equal by the respectively receiving sub-circuits 112. Thus, while not all of the thirty-two bits of this exemplary test vector are asserted the same, all predefined sub-pluralities of four bit-signals are asserted equally.

Then, as the test vectors (i.e., data) are read, or “clocked out”, of the RAM device 102, the logic circuitry 110 is able to provide a single test-point output signal 122 indicating if even a single bit discrepancy (or more) is present within a particular double-word read form the RAM device 102. Because the RAM device 102 is understood to be address-accessible, the particular storage line within the RAM device 102 where a data discrepancy has occurred is readily determinable.

FIG. 3 depicts details of a sub-circuit 112 as introduced above in regard to the system 100 of FIG. 2. The sub-circuit 112 of FIG. 3 is typical of eight such sub-circuits 112 in the context of the logic circuitry 110 of FIG. 2. In another embodiment (not shown), other numbers of sub-circuits 112 can be defined and employed.

The sub-circuit 112 includes an AND logic gate 130 and a NOR logic gate 132. Each of the AND and NOR logic gates 130, 132 is configured to receive four bit-signals collectively referred to as bit-signals 136. Each of the bit-signals 136 is coupled to a respect one of the bit-signals within each of the signal pathways 104 of FIG. 2. As depicted in FIG. 3, the bit-signals designated [0, 8, 16 24] are shown as received by the sub-circuit 112. Other sub-circuits 112 are coupled to other designated bit-signals as read from a RAM device 102 (FIG. 2) under test. For example, and with reference to FIG. 2, another sub-circuit 112 is defined and configured to receive the four bit-signals designated [1, 9, 17, 25].

In turn, the AND logic gate 130 and the NOR logic gate 132 produce respective signals 138 and 140 in accordance with the logical evaluation that each performs on the incoming bit-signals 136. One of ordinary skill in the electrical engineering and related arts can appreciate the respective logical operations performed by the AND and NOR logic gates 130, 132. Such operations are further described hereinafter.

The sub-circuit 112 of FIG. 3 further includes an Exclusive-OR (XOR) logic gate 134. The XOR logic gate 134 is configured to receive the respective signals 138 and 140 and provide an output signal 118 as introduced above in regard to the logic circuitry 110 of FIG. 2. The overall operation of the sub-circuit 112, and the logic gates 130, 132 and 134 thereof, is depicted below in the truth table of Table 1:

TABLE 1
Sub-Circuit Truth Table

| State | Input Bits | AND | NOR | XOR | Result/Comment |
|---|---|---|---|---|---|
| “A” | 0000 | 0 | 1 | 1 | All Bits Same |
| “B” | 0001 | 0 | 0 | 0 | Not Same |
| “C” | 0010 | 0 | 0 | 0 | ″ |
| “D” | 0011 | 0 | 0 | 0 | ″ |
| “E” | 0100 | 0 | 0 | 0 | ″ |
| “F” | 0101 | 0 | 0 | 0 | ″ |
| “G” | 0110 | 0 | 0 | 0 | ″ |
| “H” | 0111 | 0 | 0 | 0 | ″ |
| “I” | 1000 | 0 | 0 | 0 | ″ |
| “J” | 1001 | 0 | 0 | 0 | ″ |
| “K” | 1010 | 0 | 0 | 0 | ″ |
| “L” | 1011 | 0 | 0 | 0 | ″ |
| “M” | 1100 | 0 | 0 | 0 | ″ |
| “N” | 1101 | 0 | 0 | 0 | ″ |
| “O” | 1110 | 0 | 0 | 0 | ″ |
| “P” | 1111 | 1 | 0 | 1 | All Bits Same |

The Table 1 above reveals the respective internal and overall operations of the sub-circuit 112 of FIG. 3. As shown, a total of sixteen different input states respectively labeled “A” through “P” are depicted. These sixteen states represent all possible binary conditions for the four input bit-signals 136 in terms of logical values “one” or “zero” (i.e., asserted high or low, etc.). The respective outputs of the AND logic gate 130 and the NOR logic gate 132 are also shown for each state. By inspection, it is readily apparent that the logic gates 130 and 132 provide a different output signal assertion only when the respective input bit-signals 136 are all of the same logical value.

Specifically, the AND logic gate 130 provides a signal 138 that is asserted “one” only when all of the bit-signals 136 are asserted “one” (i.e., input state “P”). In comparison, the NOR logic gate 132 provides a signal 140 that is asserted “one” only when all of the bit-signals 136 are asserted “zero” (i.e., input state “A”). In turn, the XOR logic gate 134 provides an output signal 118 that is asserted “one” only when one or the other (but not both) of signals 138 or 140 is asserted “one” (i.e., input states “A” and “P” only). Under all other input states “B” through “O”, the XOR gate provides a signal 118 that is asserted “zero”. The output signal 118 routed to the AND logic gate 120 of the logic circuitry 110 of the system 100 of FIG. 2.

Exemplary Method

FIG. 4 is a flow diagram 200 depicted method steps in accordance with one embodiment. While the flow diagram 200 depicts particular steps and order of execution, it is to be understood that other methods, each respectively including and/or omitting these or other steps can also be used in accordance with the present teachings.

At step 202, one or more known test vectors are written into a RAM device to be tested. Such test vectors typically include one or more sub-pluralities of bits, wherein all bits are set to “one” or all “zero” within a particular sub-plurality. In any case, sufficient test vectors are written to the RAM device to fill all of the device, or to a selected address or addresses, within the RAM device. In this way, all or selected portions of the RAM device can be subjected to storage and retrieval (i.e., write and read) integrity testing.

At step 204, data is read from the RAM device, one line at a time in address-selective succession. Thus, plural bit-signals are read from the RAM device in count-dependence upon the width of line storage (e.g., thirty-two, sixty-four, etc.) of the particular RAM under test.

At step 206, the plural bit signals are segregated into sub-pluralities, or groupings, of bit-signals. In one exemplary embodiment, a RAM device being thirty-two bits wide has its bit-signals segregated into eight sub-pluralities of four bit-signals each. Other segregation schemes corresponding to other embodiments can also be used.

At step 208, each of the sub-pluralities of bit signals is independently tested to determine if all bit-signals (e.g. four, etc.) therein are of equal logical value. An output signal indicating equality or non-equality is provided or generated for each of the sub-pluralities.

At step 210, the equality/non-equality determinations made for each of the sub-pluralities are collectively evaluated. If all sub-pluralities indicated equality, then an overall output signal is asserted accordingly and provided. Otherwise, if even a single sub-plurality indicates non-equality, then the overall output signal is asserted to indicate non-equality.

### CONCLUSION

The various embodiments described above can substantially expedite testing of RAM devices and other memory device types. The logic circuitry provided herein can be suitably adapted numerous storage topologies such as, for example, 8 k lines by 32 bits wide, 4 k line by 64 bits wide, etc. Overall system complexity is reduced and the total line-by-line storage capacity of a RAM device can be evaluated during a single pass of testing.

Although the invention has been described in language specific to structural features and/or methodological acts, it is to be understood that the invention defined in the appended claims is not necessarily limited to the specific features or acts described. Rather, the specific features and acts are disclosed as exemplary forms of implementing the claimed invention.

What is claimed is:

1. A logic circuit configured to:
receive at least four bit-signals from a memory device; and
provide an output signal indicating equality if the at least four bit-signals are all of the same logical value.

2. The logic circuit of claim 1, wherein the logic circuit comprises an AND logic gate and a NOR logic gate and an Exclusive-OR logic gate, and wherein the AND logic gate and the NOR logic gate are coupled to respective inputs of the Exclusive-OR logic gate.

3. The logic circuit of claim 2, wherein the output signal is provided by the Exclusive-OR logic gate.

4. The logic circuit of claim 2 and further comprising another AND logic gate, wherein:
the Exclusive-OR logic gate is coupled to an input of the other AND logic gate; and
another output signal is provided by the other AND logic gate.

5. The logic circuit of claim 1, wherein the logic circuit is further configured such that the output signal indicates equality only if: (a) the at least four bit-signals are all of a low logical value; or (b) if the at least four bit-signals are all of a high logical value.

6. The logic circuit of claim 1, wherein the at least four bit-signals is further defined as a sub-plurality of at least thirty-two bit signals simultaneously read from the memory device.

7. The logic circuit of claim 1, wherein the logic circuit is defined by an application specific integrated circuit (ASIC).

8. An electronic testing system, comprising:
one or more logic sub-circuits each configured to receive a respective sub-plurality of a plurality of bit-signals and provide a test signal indicating equality if the sub-plurality of bit-signals are all of equal logical value; and
a logic circuit configured to receive the test signals from the one or more logic sub-circuits and provide an output signal indicating equality if all of the test signals indicate equality.

9. The electronic testing system of claim 8, further comprising an interface configured to receive a random access memory (RAM) device, wherein the plurality of bit-signals is provided by the RAM device during a testing operation.

10. The electronic testing system of claim 9, further comprising circuitry configured to input one or more test vectors into the RAM device during the testing operation.

11. The electronic testing system of claim 10 wherein at least four bits within each test vector are all of equal logical value.

12. The electronic testing system of claim 8 wherein each of the one or more logic sub-circuits comprises:
an AND logic gate configured to receive the sub-plurality of bit-signals and provide a first signal;
a NOR logic gate configured to receive the sub-plurality of bit-signals and provide a second signal; and
an Exclusive-OR logic gate configured to receive the first and second signals and to provide the test signal indicating equality if the sub-plurality of bit signals are all of equal logical value.

13. The electronic testing system of claim 8 wherein the one or more logic sub-circuits and the logic circuit are defined by an application specific integrated circuit (ASIC).

14. The electronic testing system of claim 8 wherein the plurality of bit-signals is further defined as at least thirty-two bit signals.

15. A method for testing a memory device, comprising:
receiving a plurality of bit-signals from a memory device under test;
determining if a sub-plurality of the bit-signals are all of equal logical value; and
providing an output signal corresponding to the determination.

16. The method of claim 15, further comprising:
segregating the plurality of bit-signals into at least two sub-pluralities of bit-signals; and
determining for each sub-plurality if all of the bit-signals are of equal logical value.

17. The method of claim 15, further comprising inputting at least one test vector into the memory device prior to the receiving a plurality of bit-signals.

18. The method of claim 15 wherein the plurality of bit-signals is defined by at least thirty-two bit-signals.

19. The method of claim 15 wherein the method is performed by way of an electronic testing system.

20. The method of claim 15 wherein the output signal is provided if: (a) all of the bit-signals within the sub-plurality are of a low logical value, or (b) all of the bit-signals within the sub-plurality are of a high logical value.
